(19) United States
(12) Patent Application Publication
(10) Pub. No.: US 2015/0155463 A1
(43) Pub. Date: Jun. 4, 2015

(54) THERMOELECTRIC MODULE AND METHOD FOR PRODUCING A THERMOELECTRIC MODULE

(71) Applicant: VACUUMSCHMELZE GMBH & CO. KG, Hanau (DE)

(72) Inventors: Joachim GERSTER, Alzenau (DE); Alberto BRACCHI, Hanau (DE); Michael MULLER, Woerth (DE)

(73) Assignee: VACUUMSCHMELZE GMBH & CO. KG, Hanau (DE)

(21) Appl. No.: 14/615,909

(22) Filed: Feb. 6, 2015

Related U.S. Application Data
(63) Continuation of application No. 13/571,912, filed on Aug. 10, 2012.

(30) Foreign Application Priority Data
Aug. 10, 2011 (DE) 102011052565.3

(51) Int. Cl. H01L 35/10; H01L 35/32; H01L 35/34

(52) U.S. Cl. CPC H01L 35/10; H01L 35/34; H01L 35/32

(57) ABSTRACT

A thermoelectric module which has at least one thermoelectric element for converting energy between thermal energy and electrical energy. The at least one thermoelectric element has a first surface and a second surface opposite the first surface. The thermoelectric module further has a first electrode, the first electrode having at least a first region which is arranged directly on the first surface and a second electrode, the second electrode having at least a second region which is arranged directly on the second surface. At least one of the first region and the second region has a metal alloy which exhibits an Invar effect.

This application claims benefit of the filing date of DE 10 2011 052 565.3, filed on Aug. 10, 2011, the entire contents of which are incorporated herein for all purposes.

### BACKGROUND

1. Field

Disclosed herein is a thermoelectric module, a heat engine, a heating element and a vehicle having a thermoelectric module and a method for producing a thermoelectric module.

2. Description of Related Art

Thermoelectric effects, which are also referred to as TE effects, allow the direct conversion of thermal energy into electrical energy and vice versa. Depending on the application, a distinction is made between the Seebeck effect and the Peltier effect.

The Peltier effect describes that an electric current in a material is associated with a thermal current. The relationship between the thermal current \dot{Q} and the electric current I is referred to as the Peltier coefficient Π. The following relationship applies: n=\dot{Q}/I. In a closed current circuit comprising two conductors having different Peltier coefficients, the thermal balance at the contacts is not balanced and heating of one contact occurs whilst the other contact becomes cooler.

However, the Seebeck effect sets out that a temperature difference between two ends of a material results in the formation of an electric voltage proportional to the temperature difference. The relationship between the voltage ΔU and the temperature difference ΔT is referred to as the Seebeck coefficient S. The following relationship applies: s=ΔU/ΔT.

The thermoelectric effects have a technical application, for example, in thermoelements for measuring temperature, thermoelectric modules (TE modules) for cooling or heating and in thermoelectric modules for producing electric current. Thermoelectric modules for cooling or heating are also referred to as Peltier modules whilst modules for producing electric current are also referred to as thermoelectric generators (TEGs).

US 2010/0167444 A1 discloses a method for producing a thermoelectric module. The thermal expansion coefficients of a first electrode and a second electrode are substantially identical to the expansion coefficients of a first thermoelectric material and a second thermoelectric material. To that end, metals which have a higher expansion coefficient than the thermoelectric materials are combined with metals which have a lower expansion coefficient than the thermoelectric materials.

### SUMMARY

One object of certain embodiments disclosed herein is to provide a thermoelectric module which allows reliable operation with high temperature differences and is simple to produce or to further process. Another object is to provide a method for producing a corresponding thermoelectric module.

In one embodiment is disclosed a thermoelectric module which comprises at least one thermoelectric element for converting energy between thermal energy and electrical energy. The at least one thermoelectric element comprises a first surface and a second surface opposite the first surface. The thermoelectric module further comprises a first electrode, the first electrode having at least a first region which is arranged directly on the first surface and a second electrode, the second electrode having at least a second region which is arranged directly on the second surface. At least one of the first region and the second region comprises a metal alloy which exhibits an Invar effect.

In this instance, and in the remainder of the text, the term “a metal alloy exhibiting an Invar effect” is intended to be understood to be an alloy which has a negative magnetic volume striction of the crystal lattice (volume magnetostriction) owing to its elemental composition. As a result, corresponding alloys may have very small or sometimes negative thermal expansion coefficients (coefficient of thermal expansion or CTE) within specific temperature ranges because the decrease of the magnetic volume striction in the event of a temperature increase compensates at least partially for the expansion produced by lattice oscillations.

Also disclosed herein are embodiments of a thermoelectric module which can also be operated reliably with high temperature differences. Reliable operation even with high temperature differences is particularly advantageous if the thermoelectric module is in the form of or is operated as a generator because, typically in that instance, high temperature differences occur during operation of the thermoelectric module. This is achieved according to the invention in that at least one of the first region and the second region of the first electrode or the second electrode, that is to say, the first region and/or the second region, comprises a metal alloy which exhibits an Invar effect. It is thereby possible to provide electrode materials whose thermal expansion coefficient is adapted to the thermoelectric materials which are used as members in a thermoelectric module. In particular, the embodiments allow the provision of adapted electrode materials for thermoelectric materials having a relatively small thermal expansion coefficient typically of a maximum of 12-10⁻⁶ l/K, for example, for skutterudites or half-Heusler alloys. Adapted electrodes comprising metals such as Cu, Ni, Ag or Au particularly cannot be readily obtained for those materials.

Owing to the adaptation of the expansion coefficient of the first electrode and/or the second electrode, the thermoelectric module embodiment disclosed herein affords the advantage that the thermomechanical loads produced between a hot side and a cold side of the thermoelectric module by different expansions during an adjustment of a temperature difference are minimised at the boundary face between the thermoelectric element and the first or second electrode. The thermoelectric module can thereby be operated with higher temperature differences without any occurrence of damage to the thermoelectric module brought about by thermomechanical loads. Consequently, the capabilities of the thermoelectric materials used can be exploited as completely as possible. The application of higher temperature differences further advantageously allows an increase in the degree of efficiency of the thermoelectric module.

The adaptation of the expansion coefficient further allows, owing to the reduction in the thermal loads, an increase in the service-life of the thermoelectric module particularly in the case of thermally cyclical loading.

In order to use the method known from US 2010/0167444 A1 for skutterudites as a thermoelectric material, it is possible to consider only refractory metals such as W, Mo, Nb, Ta, Zr, Cr, V and Ti as metals having a relatively low expansion coefficient. The disadvantage is that refractory metals are typically brittle and have high melting points. In order to adjust the expansion coefficient of the alloy to the desired value, a high proportion of the refractory metals is still necessary, for example, at least 50% W in WₓCu₁₋ₓ. The resultant alloys are consequently difficult to process, whereby the costs for producing a thermoelectric module are further increased.

In contrast, the metal alloys according to the invention are easy to produce and to further process in comparison with the Cu—W or Cu—Mo electrode materials known from US 2010/0167444 A1. It is thereby possible advantageously to reduce the production costs of a thermoelectric module according to the invention.

The at least one of the first region and the second region may completely consist of the metal alloy which exhibits an Invar effect. Furthermore, the electrode which comprises the corresponding region, that is to say, the at least one of the first electrode and the second electrode, or also both electrodes, may completely consist of the metal alloy which exhibits an Invar effect. As further explained below, however, it is also possible for the at least one of the first electrode and the second electrode to comprise other electrically conductive materials, in particular other metals or metal alloys, in addition to the metal alloy which exhibits an Invar effect.

In a preferred embodiment, the thermoelectric module further has a first insulation layer for electrically insulating the first electrode from a heat source, the first insulation layer being arranged on the first electrode in an at least partially direct manner.

The thermoelectric module may further have a second insulation layer for electrically insulating the second electrode from a heat sink, the second insulation layer being arranged on the second electrode in an at least partially direct manner.

The embodiments mentioned allow electrical short-circuits to be reliably avoided owing to the provision of the corresponding insulation layers. The use of electrode materials according to the present invention further allows adaptation of the thermal expansion coefficient of the first or second electrode to the ceramic materials which are preferably used as an insulation layer in a thermoelectric module. It is thereby possible to minimise loads which are produced owing to different expansions during an adjustment of a temperature difference between the hot side and the cold side of the thermoelectric module at the boundary face between the first or second electrode and the first or second insulation layer, respectively.

The metal alloy is preferably a component of an alloy system selected from the group consisting of FePt, FeNiPt, FeMn, CoMn, FeNiMn, CoMnFe, CrMn, CrCo, CrFe, NiFe and NiCoFe. These alloy systems are particularly suitable for exploiting the Invar effect according to the invention in order to adapt the expansion coefficient.

The metal alloy has, in one embodiment of the invention, a composition which substantially consists of

NiₐMn_{b}Si_{c}Cr_{d}CₑFe_{f},

with
0.1% by weight≦b≦0.5% by weight,
0.05% by weight≦c≦0.3% by weight,
0% by weight≦d≦8.0% by weight,
0% by weight≦e≦0.03% by weight,
43.0% by weight≦f≦67.0% by weight,
   incidental impurities≦1.0% by weight; balance Ni.

The following preferably applies:
0.2% by weight≦b≦0.4% by weight,
0.1% by weight≦c≦0.2% by weight,
0.9% by weight≦d≦6.0% by weight,
0% by weight≦e≦0.02% by weight and
44.5% by weight≦f≦65.0% by weight.

In particular, the following may apply:
43.0% by weight≦f≦50.0% by weight.

The metal alloy may in particular have a composition selected from the group consisting of NisiFe₄₉, Ni₅₄Fe₄₆, Ni_{47.3}Mn_{0.2}Si_{0.2}Cr₆Fe_{45.9}, Ni_{51.3}Mn_{0.4}Si_{0.1}Cr_{0.9}Fe_{46.4}, Ni_{50.5}Mn_{0.4}Si_{0.1}Fe_{48.7}, Ni_{51.25}Mn_{0.4}Si_{0.1}Fe_{48.1} and Ni_{54.4}Mn_{0.2}Si_{0.1}Fe_{44.5}, where the balance lacking in respect of 100% by weight consists of elements from the group Cr, C, Co, Cu, Al, Mo, Ti and other inevitable impurities.

In another embodiment according to the invention, the metal alloy has a composition which substantially consists of

NiₐCo_{b}Si_{c}Cr_{d}FeₑMn_{f},

with
26.0% by weight≦a≦32.0% by weight,
15.0% by weight≦b≦25.0% by weight,
0% by weight≦c≦2.0% by weight,
0% by weight≦d≦2.0% by weight,
0% by weight≦f≦2.0% by weight,
   incidental impurities≦1.0% by weight; balance Fe.

The following preferably applies:
28.0% by weight≦a≦30.0% by weight,
17.0% by weight≦b≦23.0% by weight,
0% by weight≦c≦1.0% by weight,
0% by weight≦d≦1.0% by weight and
0% by weight≦f≦1.0% by weight.

The metal alloy may in particular have a composition selected from the group consisting of Ni₂₈Co₂₁Fe₅₁, Ni₂₈Co₂₃Fe₄₉, Ni₂₉Co₁₈Fe₅₃, Ni_{28.95}Co_{17.4}Fe₅₃, Ni_{29.5}Co_{17.1}Fe₅₃ and Ni₂₈Co_{22.8}Fe_{48.4}, where the balance lacking in respect of 100% by weight consists of elements from the group Si, Cr, C, Mn, Cu, Al, Mo, Ti and other inevitable impurities.

In order to compare the temperature-dependent, thermal expansion of different materials, the mean linear expansion coefficient α(T) in relation to a reference temperature T₀ is typically used. This is defined as α(T)=(L−L₀)/[L₀(T−T₀)], where L is the length of the sample at temperature T and L₀ is the length of the sample at the reference temperature T₀. Ambient temperature (room temperature, RT) is taken as a basis as the reference temperature here and in the remainder of the text.

In addition to the mean linear expansion coefficient α(T), which is also referred to as the thermal longitudinal expansion coefficient or as thermal expansion, the thermal spatial expansion coefficient γ which is also referred to as the spatial expansion coefficient, volume expansion coefficient or cubic expansion coefficient may also be used for the comparison. The following applies to isotropic solid state bodies:

γ=3·α.

In a preferred embodiment, the metal alloy has a thermal expansion coefficient α_{El} which is between a thermal expansion coefficient α_{TE} of the at least one thermoelectric element and a thermal expansion coefficient α_{Iso} of the first and/or second insulation layer. As a result, there applies in this embodiment α_{Max}≧α_{El}≧α_{Min}, where α_{Min} denotes the minimum from α_{TE} and α_{Iso} and α_{Max} denotes the maximum from α_{TE} and α_{Iso}, that is to say, α_{Min}=Min{α_{TE}; α_{Iso}} and α_{Max}=Max{α_{TE}; α_{Iso}}. In particular, it may be the case that α_{Max}>α_{El}>α_{Min}. In one embodiment, there applies α_{TE}≧α_{El}α_{Iso}. Owing to the embodiments mentioned, there are provided electrode materials or a construction of the first and/or second electrode which allow simultaneous adaptation of the expansion of the first and/or second electrode both to the thermoelectric material of the thermoelectric element and to the preferably ceramic materials of the first and/or second insulation layer to an improved degree. The relationships mentioned apply particularly preferably to a temperature range from 100° C. to 600° C., that is to say, α_{Max}(T)≧α_{El}(T)≧α_{Min}(T) for 100° C.≦T≦600° C. Particularly if the thermoelectric module is in the form of or is operated as a generator, this is particularly advantageous because, typically in this case, high temperature differences occur during operation of the thermoelectric module.

Furthermore, there preferably applies |α_{TE}−α_{El}|≦|α_{El}−α_{Iso}|. There is taken as a basis the consideration that the fracture toughness of the thermoelectric materials is typically lower than that of the preferably ceramic insulation layers, whereby the thermoelectric materials can typically withstand smaller thermal loads than the insulation layers. This circumstance is taken into particular consideration by the thermal expansion coefficient α_{El} of the metal alloy being adapted in accordance with the condition mentioned.

For example, there applies to the thermal expansion coefficient α_{El} of the metal alloy 5·10⁻⁶ l/K≦α_{El}≦12·10⁻⁶ l/K. The thermal expansion coefficient α_{El} thereby corresponds substantially to the thermal expansion coefficients of skutterudites and half-Heusler alloys.

In another embodiment of the invention, the at least one of the first electrode and the second electrode has at least a first layer and a second layer, at least the first layer comprising the metal alloy. This embodiment takes as a basis the consideration that simultaneous minimising of the thermal loads at the boundary face between the at least one of the first electrode and the second electrode and the thermoelectric material and the boundary face between the at least one of the first electrode and the second electrode and the first or second insulation layer is particularly readily possible if the expansion coefficient of the electrode has a gradient between the boundary faces electrode/thermoelectric material and electrode/insulation layer. Therefore, the electrode does not consist of a homogeneous material but instead has a structure comprising at least a first layer and a second layer, the expansion coefficient of at least the first layer being adjusted by using the Invar effect.

The first layer may have a thermal expansion coefficient α_{El}¹ and the second layer may have a second material having a thermal expansion coefficient α_{El}², where α_{Max}≧α_{El}¹≧α_{El}²≧α_{Min}, where α_{Min} again denotes the minimum from α_{Iso} and α_{TE} and α_{Max} denotes the maximum from α_{Iso} and α_{TE}. For example, there applies α_{TE}≧α_{El}¹≧α_{El}²≧α_{Iso}. The thermal loads can thereby be taken up by the boundary faces electrode/thermoelectric material and electrode/insulation layer to a further improved degree and localised practically completely in the electrode. In a particularly preferable manner, the relationships mentioned apply to a temperature range from 100° C. to 600° C., that is to say, α_{Max}(T)≧α_{El}¹(T)≧α_{El}²(T)≧α_{Min}(T) for 100° C.≦T≦600° C.

The first layer and the second layer are preferably welded or soldered to each other. This allows simple and reliable connection of the layers mentioned.

In another embodiment of the invention, the at least one of the first electrode and the second electrode has a plurality of layers 1 to n, with n≧3, the first layer having a first material having a thermal expansion coefficient α_{El}¹ and the nth layer having an nth material having a thermal expansion coefficient α_{El}ⁿ, where, α_{Max}≧α_{El}¹≧α_{El}²> . . . >α_{El}ⁿ⁻¹>α_{El}ⁿ≧α_{Min}, where α_{Min} again denotes the minimum from α_{Iso} and α_{TE} and α_{Max} denotes the maximum from α_{Iso} and α_{TE} and where at least one of the plurality of layers 1 to n has the metal alloy. The thermal loads can again be further reduced by introducing the plurality of layers in the electrode. For example, there applies α_{TE}≧α_{El}¹>α_{El}²> . . . >α_{El}ⁿ⁻¹>α_{El}ⁿ≧α_{Iso}. The relationships mentioned apply in a particularly preferable manner to a temperature range from 100° C. to 600° C., that is to say, α_{Max}(T)≧α_{El}¹(T)>α_{El}²(T)> . . . >α_{El}ⁿ⁻¹(T)>α_{E}ⁿ(T)≧α_{Min}(T) for 100° C.≦T≦600° C.

Furthermore, the at least one of the first electrode and the second electrode may preferably have a first layer, the first layer having the metal alloy and a chemical composition of the first layer changing over the layer thickness from a first composition to a second composition different from the first composition. The boundary compositions are selected in such a manner that the expansion coefficient of the electrode at the boundary face is adapted to the thermoelectric material or to the first and/or second insulation layer, respectively. As a result, a gradient of the expansion coefficient of the electrode may be achieved between the boundary faces electrode/thermoelectric material and electrode/insulation layer by varying the composition within a layer.

The at least one thermoelectric element preferably has a material selected from the group consisting of skutterudites, half-Heusler alloys, zintl phases, silicides, clathrates, Si—Ge and oxides. These materials are particularly suitable for use in a thermoelectric element.

In another embodiment of the invention, the first insulation layer and/or the second insulation layer has/have a material selected from the group consisting of AlN, Al₂O₃ and Sis₃N₄. The materials mentioned have good thermal conductivity, whereby effective heat conduction from the heat source or to the heat sink is enabled.

In a preferred embodiment, the metal alloy has a Curie temperature T_{C}, where T_{C}>400° C. As a result, it is possible to exploit the Invar effect up to the typical maximum temperatures of use of skutterudites and half-Heusler alloys of from 400° C. to 600° C. and therefore up to the maximum application or operating temperatures of the thermoelectric module. Otherwise, that is to say, if the Curie temperature is exceeded during operation of the thermoelectric module, the expansion coefficient of the metal alloy exhibiting the Invar effect would also increase abruptly, which could result in an occurrence of thermomechanical loads.

In another embodiment, the metal alloy has a fracture toughness K_{Ic}, where K_{Ic}≧50 MPa m^{1/2}. In particular, it may be the case that K_{Ic}≧80 MPa m^{1/2}. The metal alloy has a high level of ductility. It is thereby readily possible to dissipate remaining thermomechanical loads in the case of incomplete adaptation of the expansion coefficients by means of elastic and also plastic expansion in the electrode material, whereby damage to the thermoelectric module may be avoided to a further improved extent.

The thermoelectric module is preferably provided as a thermoelectric generator. The thermoelectric module may further be provided as a Peltier module. The fundamental construction of both types of module is substantially the same and, consequently, a Peltier module can typically be operated as a thermoelectric generator and vice versa, substantially higher temperature differences typically occurring during operation in a thermoelectric generator. Whereas an electric current is produced in a thermoelectric generator by applying an external temperature gradient, an external direct current is applied in a Peltier module. Heat at one module side is absorbed by that current and discharged at the other side which results in the cooling and heating effect. The direction of the heat flow may be influenced by reversing the direction of current.

The invention further relates to a heat engine which has at least one thermoelectric module according to one of the above-mentioned embodiments. The heat engine may particularly be in the form of an internal-combustion engine. In a construction of the thermoelectric module as a thermoelectric generator, waste heat of the heat engine or the internal-combustion engine may thereby be used to generate electrical current therefrom.

The invention further relates to a vehicle which has at least one thermoelectric module according to one of the above-mentioned embodiments. In particular, the vehicle may be provided as a motor vehicle, for example, as a passenger car or a lorry.

In one embodiment, the at least one thermoelectric module is provided as a thermoelectric generator and is arranged in an exhaust system of an internal-combustion engine of the vehicle. In another embodiment, the at least one thermoelectric module is provided as a thermoelectric generator and is arranged in a cooling system of an internal-combustion engine of the vehicle. Furthermore, a combination of the two embodiments mentioned is also possible. It is thereby possible to use waste heat in the exhaust system or in the cooling system of the vehicle to produce electrical current for the vehicle, whereby the fuel consumption of the vehicle and therefore the emission of combustion gases can advantageously be reduced.

The invention further relates to a heating element which has at least one thermoelectric module according to one of the above-mentioned embodiments. It is thereby possible to use a portion of the heat produced by means of the heating element to produce electrical current therefrom in a construction of the thermoelectric module as a thermoelectric generator.

Another field of application for a thermoelectric module according to one of the above-mentioned embodiments is provided by low-temperature or cryogenic applications in which temperature differences at low temperatures can be used to generate electrical current.

The invention further relates to a method for producing a thermoelectric module according to one of the above-mentioned embodiments, the metal alloy being deformed before being applied to the at least one of the first electrode and the second electrode and, furthermore, soft-annealing of the deformed metal alloy being carried out.

There is taken as a basis the consideration that the expansion coefficient of the alloys having the Invar effect is typically dependent on the degree of a plastic deformation. If the alloy is present in a deformed state, for example, as a cold-rolled strip, the recovery and recrystallisation effects promoted at the high application temperatures may consequently result in a change of the expansion coefficient during use. In order to avoid this, it has been recognised in the context of the present invention that it is advantageous to neutralise the deformation by soft-annealing the alloy before use. It is thereby possible to prevent fluctuations of the thermal expansion behaviour of the electrode materials owing to ageing and consequently to improve the long-term stability of the thermoelectric module.

The soft-annealing of the deformed metal alloy is preferably carried out under a hydrogen atmosphere. The soft-annealing of the deformed metal alloy may further be carried out at a temperature T, with 700° C.≦T≦1200° C. and preferably 900° C.≦T≦1000° C.

Other embodiments relate to the use of a metal alloy which exhibits an Invar effect as a material of at least one electrode of a thermoelectric module.

### BRIEF DESCRIPTION OF DRAWINGS

The invention will now be explained in greater detail with reference to the appended Figures, which are intended to illustrate, not limit the scope of the appended claims, and in which:

FIG. 1 is a schematic diagram that illustrates a thermoelectric module according to a first embodiment of the invention;

FIG. 2 is a schematic diagram that illustrates a thermoelectric module according to a second embodiment of the invention;

FIG. 3 is a schematic diagram that illustrates a thermoelectric module according to a third embodiment of the invention;

FIG. 4 is a schematic diagram that illustrates a thermoelectric module according to a fourth embodiment of the invention;

FIG. 5 is a graph that illustrates mean linear expansion coefficients of a number of Ni—Fe alloys and Ni—Co—Fe alloys according to the invention in relation to ambient temperature in comparison with substrate ceramic materials and thermoelectric materials.

### DETAILED DESCRIPTION OF SPECIFIC EMBODIMENTS

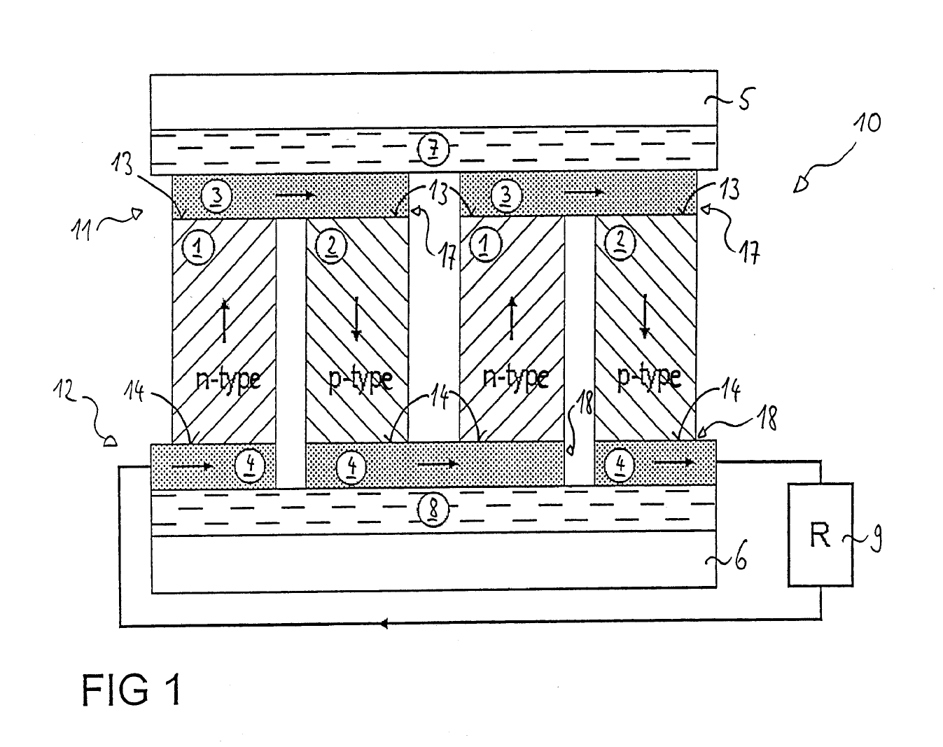

FIG. 1 illustrates a thermoelectric module 10 in the form of a thermoelectric generator (TEG) according to a first embodiment of the invention.

As schematically illustrated in FIG. 1, the thermoelectric module 10 in the illustrated embodiment has thermoelectric elements 1 and 2 which are arranged in pairs, which are also referred to as members and which are connected to each other by electrically conductive contact layers in the form of electrodes 3 and 4. In the illustrated embodiment, the thermoelectric elements 1 and 2 each have a first surface 13 and a second surface 14 opposite the first surface 13. The first electrode 3 is arranged partially directly, that is to say, immediately, on the first surface 13 of the thermoelectric elements 1 and 2 and the second electrode 4 is arranged partially directly, that is to say, immediately, on the second surface 14 of the thermoelectric elements 1 and 2. Consequently, a first region 17 of the first electrode 3 is in contact with the first surface 13 and a second region 18 of the second electrode 4 is in contact with the second surface 14.

There is used for the first member of an element pair, for example, an n-doped semiconductor material which has a negative Seebeck coefficient and for the second member a p-doped semiconductor material which has a positive Seebeck coefficient. As a result, in the illustrated embodiment, the thermoelectric element 1 has an n-doped semiconductor material and the thermoelectric element 2 has a p-doped semiconductor material.

A first side 11 of the thermoelectric module 10 is coupled to a heat source 5 and an opposite second side 12 of the thermoelectric module 10 is coupled to a heat sink 6. As a result, the first side 11 forms a hot side during operation of the thermoelectric module 10 and the opposite second side 12 forms a cold side of the thermoelectric module 10.

The members of an element pair, that is to say, the thermoelectric elements 1 and 2, are electrically connected in series in the illustrated embodiment. The opposing or complementary doping of the member materials causes the electric current in the n type member, that is to say, in the thermoelectric elements 1, to flow owing to the Seebeck effect from the cold side to the hot side and, in the p type member, that is to say, in the thermoelectric elements 2, to flow from the hot side back to the cold side. The external connections of the thermoelectric module 10 may consequently both be located on the cold side. The direction of the flow of current is schematically illustrated in FIG. 1 by means of arrows. Since the electric current and the voltage generated by a single element pair are typically relatively small, a plurality of thermoelectric elements 1 and 2 are preferably connected to each other in a thermoelectric module, there being illustrated in FIG. 1 only two pairs having thermoelectric elements 1 and 2 for reasons of clarity. Current/voltage characteristics suitable for the respective application may be provided by combinations of parallel and series connections, a series connection being illustrated in FIG. 1. An electrical consumer 9 is schematically illustrated in FIG. 1 by means of a resistance.

A temperature gradient is produced over the members in the thermoelectric module 10 which is operated as a thermoelectric generator in that the first side 11 of the thermoelectric module 10 is coupled to the heat source 5 and the opposing second side 12 is coupled to the heat sink 6. In order to prevent short-circuits, the thermoelectric elements 1 and 2 and the contact layers in the form of the electrodes 3 and 4 are electrically insulated in the illustrated embodiment by means of insulation layers 7 and 8 with respect to the heat source 5 and the heat sink 6. The first insulation layer 7 is arranged at least partially directly on the first electrode 3 and the second insulation layer 8 is arranged at least partially directly on the second electrode 4. In order to allow effective thermal conduction from the heat source 5 or to the heat sink 6 to/from the thermoelectric elements 1 and 2, respectively, the insulation layers 7 and 8 have good thermal conductivity. Therefore, ceramic materials, typically on the basis of Al₂O₃, Si₃N₄ or AlN, are preferably used for the insulation layers 7 and 8.

Two factors are particularly relevant for the application of thermoelectric generators, that is to say, the efficiency of a thermoelectric generator and the mechanical or thermal stability at the corresponding temperatures of use and during temperature cycles.

The achievable degree of efficiency of a thermoelectric generator is limited by the maximum possible degree of efficiency of a process for converting heat into electrical energy. This is given by the Carnot efficiency level η_{Carnot}=ΔT/Tₕ, with ΔT designating the temperature difference between the hot side and the cold side, that is to say, in the illustrated embodiment, between the first side 11 and the second side 12, and Tₕ designating the temperature of the hot side, that is to say, the first side 11.

The proportion of the Carnot degree of efficiency which can be exploited by a thermoelectric generator is influenced in particular by the thermoelectric efficiency of the thermoelectric materials (TE materials) used for the members. At a temperature T, highly efficient materials have a Seebeck coefficient S which is as high as possible, good electrical conductivity σ and low thermal conductivity κ. This is summarised in the thermoelectric figure of merit ZT as

$$ZT = \frac{{S}^{2} σ}{κ} \times T .$$

Particularly suitable thermoelectric materials for the thermoelectric elements 1 and 2 are so-called skutterudites on the basis of CoSb₃, or half-Heusler (HH) alloys on the basis of TiNiSn. ZT values of up to 1.4 (skutterudites) and 1.5 (HH) are possible with those materials. In comparison with the other raw materials Te, Pb and Ge which can also be used as thermoelectric materials in the form of bismuth telluride (Bi₂Te₃), lead telluride (PbTe) and silicon germanium (SiGe), those materials further have the advantage of lower raw material costs (in particular in comparison with Te and Ge), increased availability (in particular in comparison with Te) and better compatibility with the environment and health (in particular in comparison with Pb). Accordingly, the thermoelectric elements 1 and 2 preferably have at least one of the mentioned materials in the illustrated embodiment.

In addition to suitable thermoelectric materials, it is further advantageous in order to increase the efficiency for a thermoelectric generator to allow the use of temperature differences which are as great as possible because this increases the Carnot efficiency level forming the basis. To that end, in the illustrated embodiment, the electrodes 3 and 4 consist of a metal alloy exhibiting an Invar effect. In another embodiment, at least the first region 17 of the first electrode 3 and the second region 18 of the second electrode 4 have a metal alloy exhibiting an Invar effect.

There is taken as a basis the consideration that thermomechanical loads typically occur when great temperature differences are applied and during cyclical loading. Since the conventional materials used for thermoelectric modules are typically brittle materials or materials having reduced ductility, they cannot take up plastic deformations at all or only to a limited extent. If the thermomechanical loads in those materials exceed a critical value, therefore, permanent damage to the thermoelectric module may occur owing to fracturing. Thermomechanical loads in thermoelectric materials may be considered to be particularly critical.

In addition to a possible failure of the thermoelectric module owing to fracturing, the occurrence of thermal loads also constitutes a challenge involving the connection technology of the different materials of the thermoelectric module with respect to each other. Owing to the concentration of the loads in the boundary face region, that region is subjected to particular loads which can result in the individual layers becoming detached from each other.

There is taken as a basis the consideration that the formation of thermal loads may occur when the thermoelectric module 10 is heated if the materials for the members, the electrodes 3 and 4 and the insulation layers 7 and 8 have different thermal expansion coefficients (AK). In the region of the boundary face of two materials, the material having the greater thermal expansion is under compressive stress whilst tensile stresses occur in the material having the lower thermal expansion. The magnitude of the loads occurring can be reduced to a particular degree owing to the use according to the invention of a metal alloy exhibiting an Invar effect for the electrodes 3 and 4.

The use of the above-mentioned metal alloys according to the invention as electrode materials advantageously allows the expansion coefficient of the electrodes 3 and 4 to be adjusted as selectively as possible owing to the occurrence of the Invar effect. In particular, it is possible owing to the use of the Invar effect to provide electrode materials whose expansion coefficient can also be adapted to thermoelectric materials having a relatively small thermal expansion, that is to say, an expansion coefficient typically of a maximum of 12·10⁻⁶ l/K, and to the ceramic materials which are preferably used as insulation layers 7 and 8.

In particular, skutterudites and HH alloys have, with approximately 9-12·10⁻⁶ l/K, a substantially smaller thermal expansion than PbTe and Bi₂Te₃. This expansion is also substantially below the expansion of known electrode materials such as Cu, Ni, Ag or Au. When skutterudites or HH materials are combined with those known electrode materials, the electrode expands during heating more than the thermoelectric materials. Powerful tensile stresses in the members may thereby occur in the known electrode materials and are particularly damaging in terms of the propagation of fissures and fracturing. It is possible to prevent such failure of the thermoelectric module 10 in an advantageous manner owing to the use of metal alloys exhibiting the Invar effect according to the invention as an electrode material.

In order to allow reliable operation of the thermoelectric module 10, consequently, the thermal expansion coefficients of the materials which are in contact are adapted to each other. In the illustrated embodiment, there is carried out adaptation of the electrode material to the expansion of the thermoelectric materials and the insulation layers 7 and 8.

Particularly in applications in which the thermoelectric module 10 is subjected to changing temperature loads such as, for example, during use in an exhaust line of a motor vehicle in order to recover waste gas energy, the above-mentioned effects of thermal loads may occur in a pronounced manner. Owing to the cyclical loading, fatigue mechanisms which may already result in material failure at sub-critical load amplitudes occur. Such material failure can advantageously be prevented owing to the use of metal alloys exhibiting the Invar effect according to the invention as an electrode material of the thermoelectric module 10.

The physical basis of the Invar effect is a negative magnetic volume striction of the crystal lattice (volume magnetostriction), that is to say, the presence of magnetic moments brings about an additional repulsion of the atoms away from each other.

Since the magnetic moments and thereby the repelling forces decrease as the temperature increases, a negative contribution to the expansion coefficient is produced owing to this effect up to the Curie temperature of the material. In contrast to this is the conventional thermal expansion of the crystal lattice caused by lattice oscillations when the temperature increases. By the magnitude of the magnetic volume striction effect being adjusted, therefore, it is possible to selectively compensate for the thermal expansion of the crystal lattice, whereby the resultant expansion coefficient can be adjusted within a specific range.

Suitable alloy systems which exhibit the Invar effect are, for example, FePt, FeNiPt, FeMn, CoMn, FeNiMn, CoMnFe, CrMn, CrCo, CrFe and in particular Ni—Fe alloys and Ni—Co—Fe alloys. The advantages of the Ni—Fe materials and the Ni—Co—Fe materials particularly involve the possibility of producing them with a relatively low additive level of impurities and thereby achieving a relatively high level of electrical conductivity. By the Ni or Co content being varied, the magnitude of the Invar effect can be adjusted in those alloys.

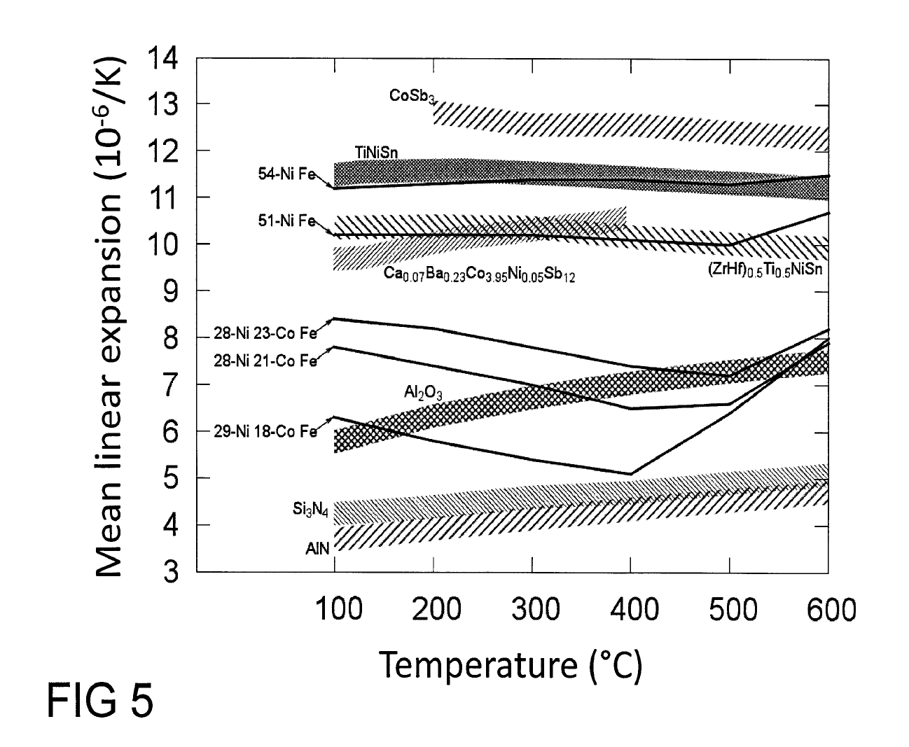

As illustrated in FIG. 5, the expansion coefficient of Ni—Fe alloys of the present invention for the Ni contents shown is in the order of magnitude of from 10·10⁻⁶ to 12·10⁻⁶ l/K, and consequently in the range of the expansion coefficients of skutterudites and HH alloys. The expansion coefficient of Ni—Co—Fe alloys of the present invention for the Ni and Co contents shown is further in the range from 5·10⁻⁶ to 8·10⁻⁶ l/K, which is similar to the expansion of the ceramic materials which are preferably used as insulation layers.

As set out in Table 1, the Curie temperatures of the alloys of the present invention illustrated in FIG. 5 are greater than 400° C. without exception. As a result, the use of the Invar effect is possible up to the maximum temperatures of use of the skutterudites and HH alloys of from 400° C. to 600° C.

TABLE 1
Curie temperatures of the Ni—Fe alloys and Ni—Co—Fe
alloys illustrated in FIG. 5.

| Alloy | Curie temperature T_{C} (° C.) |
|---|---|
| Ni₅₄Fe_{balance} | 525 |
| Ni₅₁Fe_{balance} | 495 |
| Ni₂₈Co₂₃Fe_{balance} | 510 |
| Ni₂₈Co₂₁Fe_{balance} | 480 |
| Ni₂₉Co₁₈Fe_{balance} | 425 |

It is also advantageous for the long-term stability of the thermoelectric module 10 to prevent ageing-related variations of the thermal expansion behaviour of the electrode materials. The expansion coefficient of the alloys having the Invar effect according to embodiments of the invention set out above is typically dependent on the degree of plastic deformation. If the alloy is provided in a deformed state, for example, as a cold rolled strip, the recovery and recrystallisation effects which are promoted at the high application temperatures may consequently result in a change of the expansion coefficient during use.

In order to prevent this, it has been recognised in the context of the present invention that it is advantageous to neutralise the deformation by soft-annealing of the alloy, for example, for 30 minutes at a temperature of approximately 950° C. under a hydrogen atmosphere, before use. Furthermore, the ageing process may be anticipated by a thermal processing operation of sufficient duration, typically from 2 to 4 hours, at least at from 50° C. to 100° C. above the application temperature.

In the soft-annealed state, the mentioned alloys having the Invar effect afford the additional advantage of a high level of ductility in contrast to the alloys which are proposed in US2010/0167444 A1 and which have a high proportion of refractory metal. Their fracture toughness is in the order of magnitude of 100 MPa m^{1/2}. It is thereby readily possible to dissipate residual thermomechanical loads in the event of incomplete adaptation of the expansion coefficients by means of elastic and also plastic expansion in the electrode material, whereby damage to the thermoelectric module 10 can be prevented.

As described above, it is possible using the Invar effect to produce electrode materials and electrodes 3 and 4 which are adapted to the thermal expansion of thermoelectric materials and therefore to the thermal expansion of the thermoelectric elements 1 and 2, and to the thermal expansion particularly of ceramic insulation layer materials, that is to say, in the illustrated embodiment, with respect to the thermal expansion coefficients of the insulation layers 7 and 8, respectively. When an electrode consisting of a homogeneous material is used, however, it is typically scarcely possible simultaneously to adapt the expansion of the electrode to both elements involved in the connection, that is to say, the thermoelectric material and the insulation layer. In that case, therefore, thermomechanical loads typically cannot be completely prevented. Therefore, it is particularly advantageous to adjust an expansion coefficient of the electrodes 3 and 4 that minimises the total of the loads occurring. Since the expansion coefficient of the thermoelectric material (α_{TE}) is typically greater than the expansion coefficient of the insulation layers 7 and 8 (α_{Iso}), this can be brought about in a preferred embodiment of the invention by an electrode material whose expansion coefficient α_{El} owing to use of the Invar effect is between the expansion coefficient of the thermoelectric material and the expansion coefficient of the insulation layers 7 and 8, that is to say, there preferably applies α_{Max}≧α_{El}≧α_{Min}, with α_{Min} denoting the minimum from α_{Iso} and α_{TE} and α_{Max} denoting the maximum from α_{Iso}, and α_{TE}. For example, there applies α_{TE}≧α_{El}≧α_{Iso}.

As set out in Table 2, the fracture toughness of the thermoelectric materials mentioned is typically lower than that of the preferably ceramic insulation layers 7 and 8, whereby the thermoelectric materials can typically withstand lower thermal loads than the insulation layers 7 and 8. In another preferred embodiment of the invention, therefore, an expansion coefficient α_{El} of the electrode material or the electrodes 3 and 4 is adjusted by the Invar effect and is between the expansion coefficient of the thermoelectric material, that is to say, the thermoelectric elements 1 and 2, and the expansion coefficient of the insulation layers 7 and 8, but is adapted more closely to the expansion coefficient of the thermoelectric material than to the expansion coefficient of the insulation layers 7 and 8, that is to say, there applies in this construction |α_{TE}−α_{El}|≦|α_{El}−α_{Iso}|.

TABLE 2
Fracture toughnesses of some thermoelectric
materials and ceramic materials.

| Material | Fracture toughness (Mpa · m^{1/2}) |
|---|---|
| Half-Heusler | 0.5-2 |
| Bi₂Te₃ | 1.3 |
| PbTe | 0.34 |
| Al₂O₃ | 4 |
| AlN | 2.6 |
| Si₃N₄ | 6.1 |

The typical maximum temperature of use at the hot side of the thermoelectric module 10, that is to say, the first side 11, is limited by the thermal stability of the thermoelectric material and the ZT characteristic thereof because the ZT value typically decreases substantially after a maximum is reached at relatively high temperatures. In particular, the above-mentioned skutterudites and HH alloys and PbTe are suitable for high temperatures of use of from 400° C. to 600° C.

Exemplary electrode materials for the thermoelectric module 10 having different combinations of thermoelectric materials and ceramic materials acting as insulation layers 7 and 8 are set out below.

In the embodiment illustrated in FIG. 1 of electrodes 3 and 4 consisting of a homogeneous material, for example the material combinations set out in Table 3 fulfil the condition α_{Max}≧α_{El}≧α_{Min} and in particular α_{TE}≧α_{El}≧α_{Iso}, with the expansion coefficient of the electrode material being approximately in the middle between the expansion coefficient of the thermoelectric material, that is to say, the thermoelectric elements 1 and 2, and the expansion coefficient of the insulation layers 7 and 8 and being set by the Invar effect. In Table 3 and in the following Tables, only the mean expansion coefficient between ambient temperature and 100° C. is set out in parentheses, respectively. A comparison of the expansion coefficients up to 600° C. is set out in FIG. 5.

TABLE 3
Exemplary material combinations for the thermoelectric module
10 according to the first embodiment of the invention

| No. | TE Material | Electrode material | Insulation layer |
|---|---|---|---|
| 1 | PbTe (20.4) | Ni₅₄Fe_{balance} (11.2) | AlN (3.7) |
| 2 | Bi₂Te₃ (16.4) | Ni₅₄Fe_{balance} (11.2) | Al₂O₃ (5.8) |
| 3 | CoSb₃ (12.8 | Ni₂₈Co₂₃Fe_{balance} (8.4) | Si₃N₄ (4.2) |
| | at 200° C.) | | |

Owing to the exemplary material combinations according to the invention in Table 4 set out below, the condition α_{Max}≧α_{El}≧α_{Min} is also fulfilled, and in particular α_{TE}≧α_{El}≧α_{Iso}, the expansion coefficient of the electrodes 3 and 4 further being adapted so as to be substantially closer to the expansion coefficient of the thermoelectric material.

TABLE 4
Other exemplary material combinations for the thermoelectric
module 10 according to the first embodiment of the invention

| No. | TE Material | Electrode Material | Insulation layer |
|---|---|---|---|
| 4 | CoSb₃ (12.8 at | Ni₅₄Fe_{balance} (11.2) | AlN (3.7), Si₃N₄ |
| | 200° C.) | | (4.2), or Al₂O₃ (5.8) |
| 5 | TiNiSn (11.5) | Ni₅₄Fe_{balance} (11.2) | AlN, Si₃N₄, or Al₂O₃ |
| 6 | (ZrHf)_{0.5}Ti_{0.5}NiSn | Ni₅₁Fe_{balance} (10.2) | AlN, Si₃N₄, or Al₂O₃ |
| | (10.4) | | |

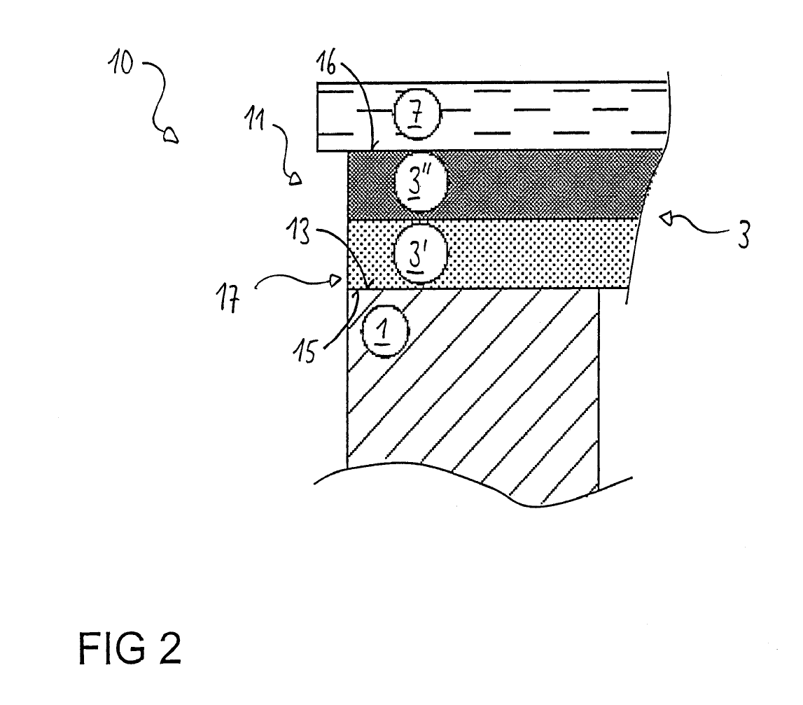

FIG. 2 illustrates a section of a thermoelectric module 10 according to a second embodiment of the invention. Components having the same functions as in FIG. 1 are indicated with the same reference numerals and are not explained again below.

The thermoelectric module 10 according to the second embodiment differs from the first embodiment illustrated in FIG. 1 in that the electrodes of the thermoelectric module 10, of which one electrode 3 is illustrated in FIG. 2, have two layers. The electrode 3 has a first layer 3′ and a second layer 3″.

The illustrated embodiment is based on the consideration that it is readily possible to simultaneously minimise the thermal loads at the two boundary faces, that is to say, the boundary face 15 between the electrode 3 and the thermoelectric material and the boundary face 16 between the electrode 3 and the insulation layer 7, if the expansion coefficient of the electrode 3 has a gradient between the boundary faces electrode 3/thermoelectric material and electrode 3/insulation layer 7. Therefore, the electrode 3 does not consist of a homogeneous material but instead has the structure comprising two layers 3′ and 3″ illustrated in FIG. 2, the expansion coefficient of at least one of the layers 3′ and 3″ being adjusted by using the Invar effect. In the illustrated embodiment, the layer 3′ consists of a first metal alloy which exhibits an Invar effect and the layer 3″ consists of a second metal alloy which is different from the first metal alloy and which exhibits an Invar effect. The layer 3′ is arranged in the first region 17 of the first electrode 3.

For the layer 3′ which is connected to the thermoelectric material, it is consequently possible to use an electrode material whose expansion coefficient is adapted to the expansion of the thermoelectric material. At the same time, an electrode material whose expansion coefficient is adapted to the expansion of the insulation layer 7 can be used for the layer 3″ which is connected to the insulation layer 7. According to the second embodiment of the invention shown, consequently, there applies α_{Max}≧α_{El}¹≧α_{El}²≧α_{Min} to the expansion coefficients of the electrode layers α_{El}¹ and α_{El}², with α_{Min} denoting the minimum from α_{Iso} and α_{TE} and α_{Max} denoting the maximum from α_{Iso} and α_{TE}. For example, there applies α_{TE}≧α_{El}¹≧α_{El}²≧α_{Iso}. The thermal loads can thereby be taken up by the boundary faces electrode 3/thermoelectric material and electrode 3/insulation layer 7 to a further improved degree and localised in the electrode 3 practically completely.

Since the electrode materials as described above have a high level of ductility in the soft state, the loads can be dissipated therein by elastic or plastic deformation without any occurrence of permanent damage to the thermoelectric module 10. Such a two-layer system may be produced, for example, by cold-welding and welding or soldering.

In a construction of the electrode 3 comprising two layers, the material combinations set out in the following Table 5 can particularly be used according to the invention.

TABLE 5
Exemplary material combinations for the thermoelectric module
10 according to the second embodiment of the invention

| | | Electrode | | |
|---|---|---|---|---|
| No. | TE Material | Layer 1 | Layer 2 | Insulation layer |
| 7 | CoSb₃ (12.8 at 200° C.) | Ni₅₄Fe_{balance} | Ni₂₈Co₂₁Fe_{balance} | Al₂O₃ (5.8) |
| | | (11.2) | (7.8) | |
| 8 | TiNiSn (11.5) | Ni₅₄Fe_{balance} | Ni₂₈Co₂₁Fe_{balance} | Al₂O₃ (5.8) |
| | | (11.2) | (7.8) | |
| 9 | (ZrHf)_{0.5}Ti_{0.5}NiSn (10.4) | Ni₅₁Fe_{balance} | Ni₂₈Co₂₁Fe_{balance} | Al₂O₃ (5.8) |
| | | (10.2) | (7.8) | |
| 10 | Ca_{0.07}Ba_{0.23}Co_{3.95}Ni_{0.05}Sb₁₂ | Ni₅₁Fe_{balance} | Ni₂₉Co₁₈Fe_{balance} | Si₃N₄ (4.2) |
| | (9.7) | (10.2) | (6.3) | |

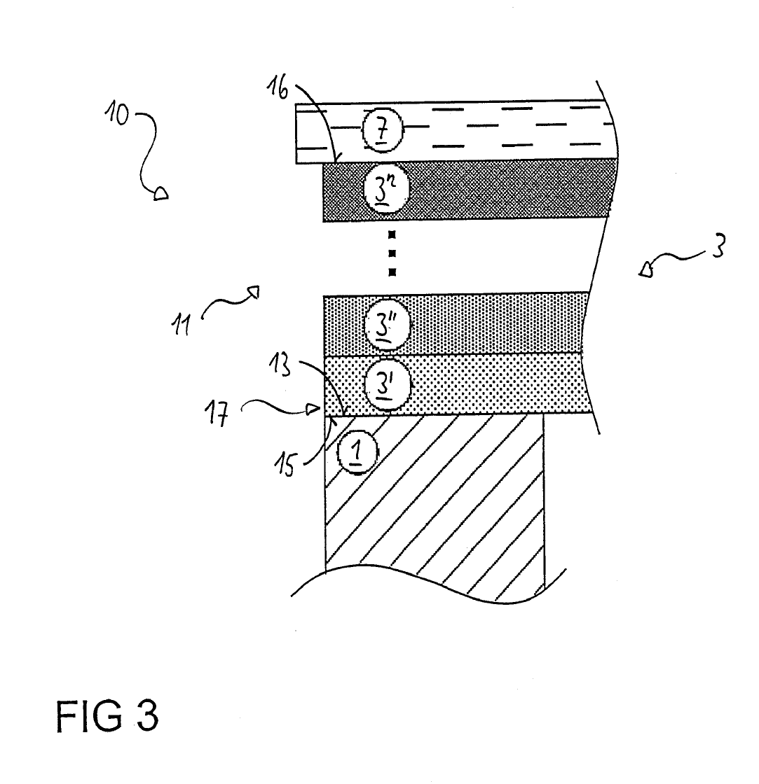

FIG. 3 illustrates a section of a thermoelectric module 10 according to a third embodiment of the invention. Components having the same functions as in the preceding Figures are indicated with the same reference numerals and are not explained again below.

The thermoelectric module 10 according to the third embodiment differs from the first embodiment illustrated in FIG. 1 in that the electrodes of the thermoelectric module 10, of which one electrode 3 is illustrated in FIG. 3, have a plurality of layers. FIG. 3 illustrates a construction of the electrode 3 comprising n layers 3′, 3″, . . . , 3ⁿ where n≧3.

By the intermediate layers being introduced in the electrode 3, the thermal loads can be further reduced again. According to the third embodiment of the invention shown, there applies α_{Max}≧α_{El}¹>α_{El}²> . . . >α_{El}^{N-1}>α_{El}ⁿ≧α_{Min} to the expansion coefficients α_{El}¹ to α_{El}ⁿ of the layers 3′, 3″, . . . , 3ⁿ of the electrode 3, where α_{Min} denotes the minimum from α_{Iso} and α_{TE} and α_{Max} denotes the maximum from α_{Iso} and α_{TE}, with the expansion coefficient of at least one layer being adjusted using the Invar effect. For example, there applies α_{TE}≧α_{El}¹>α_{El}²> . . . >α_{El}ⁿ⁻¹>α_{El}ⁿ≧α_{Iso}. In the illustrated embodiment, the layer 3′ consists of a first metal alloy which exhibits an Invar effect, the layer 3″ consists of a second metal alloy which is different from the first metal alloy and which exhibits an Invar effect and the layer 3ⁿ consists of an nth metal alloy which is different from the other metal alloys and which exhibits an Invar effect. The layer 3′ is arranged in the first region 17 of the first electrode 3.

An example of a three-layer construction of the electrode 3 according to the invention is set out in the following Table 6.

TABLE 6
Exemplary material combination for the thermoelectric module
10 according to the third embodiment of the invention

| | | Electrode | | | |
|---|---|---|---|---|---|
| No. | TE Material | Layer 1 | Layer 2 | Layer 3 | Insulation layer |
| 11 | (ZrHf)_{0.5}Ti_{0.5} | Ni₅₁Fe_{balance} | Ni₂₈Co₂₃Fe_{balance} | Ni₂₉Co₁₈Fe_{balance} | Si₃N₄ (4.2) |
| | NiSn (10.4) | (10.2) | (8.4) | (6.3) | |

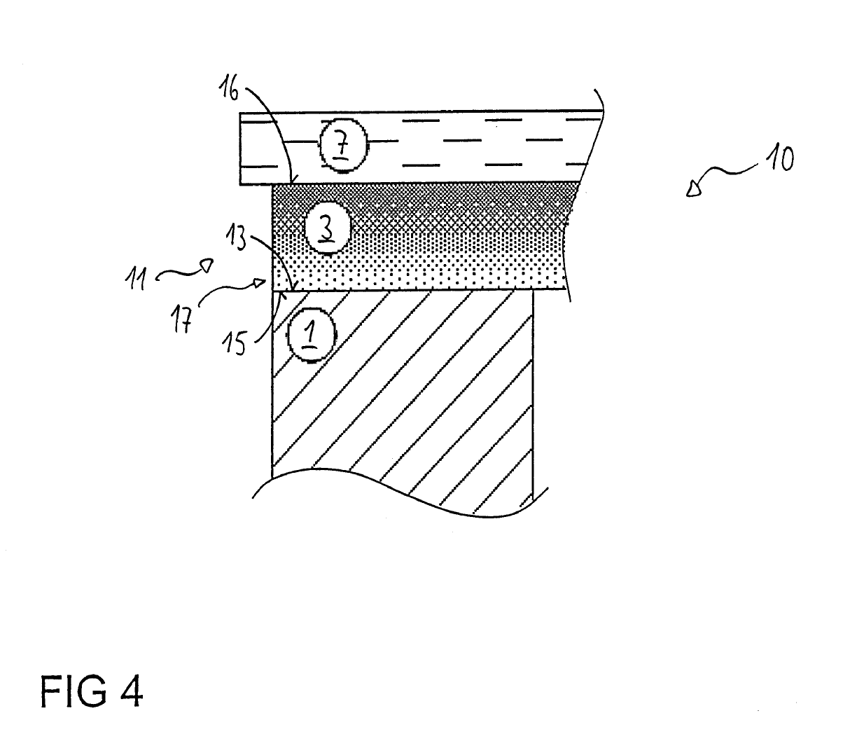

FIG. 4 illustrates a section of a thermoelectric module 10 according to a fourth embodiment of the invention. Components having the same functions as in the preceding Figures are indicated with the same reference numerals and are not explained again below.

The thermoelectric module 10 according to the fourth embodiment differs from the embodiments illustrated in the preceding Figures in that a composition of the electrodes, of which one electrode 3 is illustrated in FIG. 4, varies continuously over the thickness between two boundary compositions.

As a result, it is possible to achieve a gradient of the expansion coefficient of the electrode 3 between the boundary faces electrode 3/thermoelectric material and electrode 3/insulation layer 7 by varying the composition within a layer. The boundary compositions are selected in such a manner that the expansion coefficient of the electrode 3 at the boundary face 15 and 16 is adapted to the thermoelectric material and to the insulation layer 7, respectively. The adjustment of a concentration gradient may be carried out during the production of the electrodes by layer deposition methods, for example, sputter deposition.

An example of an electrode 3 according to the invention, in which the expansion coefficient between the boundary face 15 with respect to the thermoelectric material and the boundary face 16 with respect to the insulation layer 7 varies owing to a concentration gradient, is given by TiNiSn as the thermoelectric material having an expansion coefficient of 11.5, Al₂O₃ as the insulation layer 7 having an expansion coefficient of 5.8 and a variation of the composition of the electrode 3 from 54-Ni Fe (Ni₅₄Fe_{balance}) having an expansion coefficient of 11.2 at the boundary face 15 with respect to the thermoelectric material to 46-Ni Fe (Ni₄₆Fe_{balance}) having an expansion coefficient of 7.9 at the boundary face 16 with respect to the insulation layer 7.

FIG. 5 illustrates, as already explained above, mean linear expansion coefficients of a number of Ni—Fe alloys and Ni—Co—Fe alloys according to the invention in relation to ambient temperature in comparison with substrate ceramic materials and thermoelectric materials. The compositions of the Ni—Fe alloys and the Ni—Co—Fe alloys are set out in % by weight.

The invention having been described herein with respect to certain specific embodiments and examples, it will be understood that these embodiments and examples are not limiting of the appended claims.

### LIST OF REFERENCE NUMERALS

1 Thermoelectric element
2 Thermoelectric element
3 Electrode
3′ Layer
3″ Layer
3ⁿ Layer
4 Electrode
5 Heat source
6 Heat sink
7 Insulation layer
8 Insulation layer
9 Consumer
10 Thermoelectric module
11 Side
12 Side
13 Surface
14 Surface
15 Boundary face
16 Boundary face
17 Region
18 Region

1-34. (canceled)

35. A thermoelectric module, comprising a stack of layers comprising:
at least one thermoelectric element that converts energy between thermal energy and electrical energy, comprising a first surface,
a first electrically conductive electrode arranged on the first surface of the at least one thermoelectric element,
a first insulation layer arranged on the first electrode,
wherein a thermal expansion coefficient of the layers of the stack decreases in a direction from the thermoelectric element to the first insulation layer.

36. The thermoelectric module according to claim 35, wherein the first electrode includes a metal alloy having a thermal expansion coefficient which is between thermal expansion coefficient of the at least one thermoelectric element and a thermal expansion coefficient of the first insulation layer.

37. The thermoelectric module according to claim 35, wherein the first insulation layer comprises a first sublayer arranged on the first electrode and a second sublayer arranged on the first sublayer, the first sublayer having a thermal expansion coefficient which is greater than a thermal expansion coefficient of the second sublayer.

38. The thermoelectric module according to claim 35, wherein the first electrode comprises a first sublayer arranged on the first surface and a second sublayer arranged on the first sublayer, the first sublayer having a thermal expansion coefficient which is greater than a thermal expansion coefficient of the second sublayer.

39. The thermoelectric module according to claim 35, wherein the first insulation layer electrically insulates the first electrode from a heat source, and is arranged on the first electrode in an at least partially direct manner.

40. The thermoelectric module according to claim 39, further comprising a second insulation layer that electrically insulates a second electrode from a heat sink arranged on the second electrode in an at least partially direct manner.

41. The thermoelectric module according to claim 36, wherein the metal alloy is a component of an alloy system selected from the group consisting of FePt, FeNiPt, FeMn, CoMn, FeNiMn, CoMnFe, CrMn, CrCo, CrFe, NiFe and NiCoFe.

42. The thermoelectric module according to claim 36, wherein the metal alloy has a composition which consists essentially of
NiₐMn_{b}Si_{c}Cr_{d}CₑFe_{f},
with
0.1% by weight≦b≦0.5% by weight,
0.05% by weight≦c≦0.3% by weight,
0% by weight≦d≦8.0% by weight,
0% by weight≦e≦0.03% by weight,
43.0% by weight≦f≦67.0% by weight,
incidental impurities≦1.0% by weight; balance Ni.

43. The thermoelectric module according to claim 42, wherein
0.2% by weight≦b≦0.4% by weight,
0.1% by weight≦c≦0.2% by weight,
0.9% by weight≦d≦6.0% by weight,
0% by weight≦e≦0.02% by weight and
44.5% by weight≦f≦65.0% by weight.

44. The thermoelectric module according to claim 36, wherein the metal alloy has a composition selected from the group consisting of Ni₅₁Fe₄₉, Ni₅₄Fe₄₆, Ni_{47.3}Mn_{0.2}Si_{0.2}Cr₆Fe_{45.9}, Ni_{51.3}Mn_{0.4}Si_{0.1}Cr_{0.9}Fe_{46.4}, Ni_{50.5}Mn_{0.4}Si_{0.1}Fe_{48.7}, Ni_{51.25}Mn_{0.4}Si_{0.1}Fe_{48.1} and Ni_{54.4}Mn_{0.2}Si_{0.1}Fe_{44.5}, where the balance consists of elements from the group Cr, C, Co, Cu, Al, Mo, Ti and other impurities.

45. The thermoelectric module according to claim 36, wherein the metal alloy has a composition which consists essentially of
NiₐCo_{b}Si_{c}Cr_{d}FeₑMn_{f},
with
26.0% by weight≦a≦32.0% by weight,
15.0% by weight≦b≦25.0% by weight,
0% by weight≦c≦2.0% by weight,
0% by weight≦d≦2.0% by weight,
0% by weight≦f≦2.0% by weight,
incidental impurities≦1.0% by weight; balance Fe.

46. The thermoelectric module according to claim 45, wherein
28.0% by weight≦a≦30.0% by weight,
17.0% by weight≦b≦23.0% by weight,
0% by weight≦c≦1.0% by weight,
0% by weight≦d≦1.0% by weight and
0% by weight≦f≦1.0% by weight.

47. The thermoelectric module according to claim 45, wherein the metal alloy has a composition selected from the group consisting of Ni₂₈Co₂₁Fe₅₁, Ni₂₈Co₂₃Fe₄₉, Ni₂₉Co₁₈Fe₅₃, Ni_{28.95}Co_{17.4}Fe₅₃, Ni_{29.5}Co_{17.1}Fe₅₃ and Ni₂₈Co_{22.8}Fe_{48.4}, where the balance consists of elements from the group Si, Cr, C, Mn, Cu, Al, Mo, Ti and other impurities.

48. The thermoelectric module according to claim 36, wherein the metal alloy has a thermal expansion coefficient α_{El} which is between a thermal expansion coefficient α_{TE} of the at least one thermoelectric element and a thermal expansion coefficient α_{Iso} of the first insulation layer.

49. The thermoelectric module according to claim 48, wherein α_{Max}≧α_{El}≧α_{Min}, where α_{Min} is the minimum from α_{Iso} and α_{TE} and α_{Max} is the maximum from α_{Iso} and α_{TE}.

50. The thermoelectric module according to claim 49, wherein |α_{TE}−α_{El}|≦|α_{El}−α_{Iso}|.

51. The thermoelectric module according to claim 48, wherein 5·10⁻⁶ l/K≦α_{El}≦12·10⁻⁶ l/K.

52. The thermoelectric module according to claim 36, wherein the first electrode comprises at least a first layer and a second layer, the first layer comprising the metal alloy.

53. The thermoelectric module according to claim 52, wherein the first layer has a thermal expansion coefficient α_{El}¹ and the second layer comprises a second material having a thermal expansion coefficient α_{E1}², where α_{Max}≧α_{El}¹≧α_{El}²≧α_{Min}, where α_{Min} is the minimum from also and α_{TE} and α_{Max} is the maximum from α_{Iso} and α_{TE}.

54. The thermoelectric module according to claim 52, wherein the first layer and the second layer are welded or soldered to each other.

55. The thermoelectric module according to claim 36, wherein the first electrode comprises a plurality of layers 1 to n, with n≧3, the first layer comprising a first material having a thermal expansion coefficient α_{El}¹ and the nth layer comprising an nth material having a thermal expansion coefficient α_{El}ⁿ, wherein Error! Objects cannot be created from editing field codes, where α_{Min} is the minimum from α_{Iso} and α_{TE} and α_{Max} is the maximum from α_{Iso} and α_{TE} and wherein at least one of the plurality of layers 1 to n comprises the metal alloy.

56. The thermoelectric module according to claim 35, wherein the first electrode comprises a first layer, the first layer comprising the metal alloy and wherein the chemical composition of the first layer changes over the layer thickness from a first composition to a second composition different from the first composition.

57. The thermoelectric module according to claim 35, wherein the at least one thermoelectric element comprises a material selected from the group consisting of skutterudites, half-Heusler alloys, zintl phases, silicides, clathrates, SiGe and oxides.

58. The thermoelectric module according to claim 40, wherein the first insulation layer and/or the second insulation layer comprises a material selected from the group consisting of AlN, Al₂O₃ and Si₃N₄.

59. The thermoelectric module according to claim 36, wherein the metal alloy has a Curie temperature T_{C}, such that T_{C}≧400° C.

60. Thermoelectric module according to claim 36, wherein the metal alloy has a fracture toughness K_{Ic}, such that K_{Ic}≧50 MPa m^{1/2}.

61. A thermoelectric generator comprising the thermoelectric module according to claim 35.

62. A heat engine comprising at least one thermoelectric module according to claim 35.

63. A heat engine according to claim 62, wherein the heat engine is in the form of an internal-combustion engine.

64. A vehicle comprising at least one thermoelectric module according to claim 35.

65. The vehicle according to claim 64, wherein the at least one thermoelectric module is arranged in an exhaust system of an internal-combustion engine of the vehicle.

66. The vehicle according to claim 64, wherein the at least one thermoelectric module is arranged in a cooling system of an internal-combustion engine of the vehicle.

67. A heating element comprising at least one thermoelectric module according to claim 35.

68. A method for producing a thermoelectric module according to claim 36, comprising deforming the metal alloy before applying it to the at least one of the first region and the second region and soft-annealing the deformed metal alloy.

69. The method according to claim 68, wherein the soft-annealing of the deformed metal alloy is under a hydrogen atmosphere.

70. The method according to claim 68, wherein the soft-annealing of the deformed metal alloy is at a temperature T, such that 700° C.≦T≦1200° C.
